(19) United States
(12) Patent Application Publication
(10) Pub. No.: US 2026/0305150 A1
(43) Pub. Date: Oct. 1, 2026

(54) APPARATUS AND METHOD FOR MANUFACTURING DISPLAY APPARATUS AND ELECTRONIC DEVICE INCLUDING THE DISPLAY APPARATUS

(71) Applicant: Samsung Display Co., Ltd., Yongin-si (KR)

(72) Inventors: Byeongjun Lee, Yongin-si (KR); Jaesik Kim, Yongin-si (KR); Junghan Seo, Yongin-si (KR); Wooyong Sung, Yongin-si (KR); Seungho Yoon, Yongin-si (KR)

(21) Appl. No.: 19/630,774

(22) Filed: Mar. 27, 2026

(30) Foreign Application Priority Data
Mar. 31, 2025 (KR) 10-2025-0041442

(51) Int. Cl. H10K 71/13; B41J 2/14; B41J 2/16; B41J 2/165; B41J 3/28; B41M 5/00; C23C 14/10; H10K 59/12

(52) U.S. Cl. CPC H10K 71/13; B41J 2/1433; B41J 2/1606; B41J 2/164; B41J 2/16502; B41J 3/28; B41M 5/0047; C23C 14/10; H10K 59/1201

(57) ABSTRACT

An apparatus for manufacturing a display apparatus includes a stage on which a display substrate is seated, and a head unit disposed to face the stage and configured to spray ink onto the display substrate, where the head unit includes a first area and a second area next (adjacent) to the first area, and the head unit includes a second liquid-repelling layer continuously covering a surface of the head unit in the first area and the second area, and a first liquid-repelling layer disposed under the second liquid-repelling layer in the first area.

This application claims to Korean Patent Application No. 10-2025-0041442, filed on Mar. 31, 2025, and all the benefits accruing therefrom under 35 U.S.C. § 119, the content of which in its entirety is herein incorporated by reference.

### BACKGROUND

### 1. Field

Embodiments relate to an apparatus and method for manufacturing a display apparatus, and more particularly, to an apparatus and method for manufacturing a display apparatus, in which printing quality may be improved, and an electronic device including the display apparatus.

### 2. Description of the Related Art

Electronic devices based on mobility are widely used. As mobile electronic devices, tablet personal computers have been widely used recently in addition to small electronic devices such as mobile phones.

Such mobile electronic devices include a display apparatus to provide various functions, i.e., visual information such as images or videos, to a user. Recently, display apparatuses have become a more significant part of electronic devices, and structures are also being developed that may be bent from a flat state to a predetermined angle.

A display apparatus may include various layers formed through various processes. For example, the display apparatus may include a functional layer that performs an optical function or a color filter layer that improves color purity, and these layers may be formed through a process of discharging ink onto a display substrate, e.g., an inkjet printing process. For the inkjet printing process, an apparatus for manufacturing a display apparatus may include a head unit that discharges ink.

### SUMMARY

A head unit may be damaged during a maintenance process, and the head unit may be desired to be repaired to maintain the same quality.

Embodiments include an apparatus and method for manufacturing a display apparatus, in which printing quality may be improved.

However, it should be understood that embodiments described herein should be considered in a descriptive sense only and not for limitation of the disclosure.

Additional features will be set forth in part in the description which follows and, in part, will be apparent from the description, or may be learned by practice of the presented embodiments of the disclosure.

In an embodiment of the disclosure, an apparatus for manufacturing a display apparatus includes a stage on which a display substrate may be seated, and a head unit disposed to face the stage and configured to spray ink onto the display substrate, where the head unit includes a first area and a second area next (adjacent) to the first area, and the head unit includes a second liquid-repelling layer continuously covering a surface of the head unit in the first area and the second area, and a first liquid-repelling layer disposed under the second liquid-repelling layer in the first area.

In an embodiment, the head unit in the second area may further include a first inorganic layer disposed under the second liquid-repelling layer.

In an embodiment, an upper surface of the first liquid-repelling layer and an upper surface of the first inorganic layer may be disposed on a same plane.

In an embodiment, the second liquid-repelling layer may include a different material from a material of the first liquid-repelling layer.

In an embodiment, the head unit may include, in the first area, a first base layer portion, a first layer disposed on the first base layer portion, a first liquid-repelling layer disposed on the first layer, and a second liquid-repelling layer disposed on the first liquid-repelling layer, and in the second area, a second base layer portion, a first inorganic layer on the second base layer portion, and a second liquid-repelling layer disposed on the first inorganic layer and continuously disposed with the first area.

In an embodiment, the first layer may include an organic material.

In an embodiment, the first inorganic layer may include silicon dioxide (SiO₂).

In an embodiment, a thickness of the second base layer portion in the second area may be less than a thickness of the first base layer portion in the first area.

In an embodiment, the apparatus may further include a reinforcement layer disposed between the first inorganic layer and the second base layer portion in the second area.

In an embodiment, the reinforcement layer may include aluminum oxide.

In an embodiment, the reinforcement layer may include a metallic material.

In an embodiment, in a plan view, a nozzle hole through which ink is sprayed may be defined in the second area.

In an embodiment of the disclosure, a method for manufacturing a display apparatus includes preparing a head unit including a first area that is a normal (non-damaged) area and a second area that is a damaged area on a surface, depositing an inorganic material on the surface of the head unit, forming a second liquid-repelling layer on the surface of the head unit, and discharging ink onto a display substrate on a stage with the head unit.

In an embodiment, the first area that is the normal (non-damaged) area may include a base layer and a first liquid-repelling layer disposed on the base layer, and the second area that is the damaged area may include a base layer.

In an embodiment, the depositing the inorganic material may include depositing the inorganic material on the second area but not on the first area.

In an embodiment, the inorganic material may not be deposited on the first liquid-repelling layer.

In an embodiment, in the second area, the inorganic material may be deposited to a same plane as an upper surface of the first liquid-repelling layer of the first area.

In an embodiment, the inorganic material may include silicon dioxide (SiO₂).

In an embodiment, the forming the second liquid-repelling layer may include continuously forming the second liquid-repelling layer across the first area and the second area.

In an embodiment, in the first area, the second liquid-repelling layer may be disposed to overlap the first liquid-repelling layer.

Other features, features and advantages other than those described above will become apparent from the following detailed description, claims and drawings for practicing the disclosure.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic block diagram of an embodiment of an electronic device;

FIG. 2 is schematic diagrams of embodiments of electronic devices;

FIG. 3 is a schematic perspective view of an embodiment of a display apparatus;

FIG. 4 is a schematic cross-sectional view of an embodiment of pixels of a display apparatus;

FIG. 5 is a schematic view of optical portions of a color conversion-transmission layer of FIG. 4;

FIG. 6 is an equivalent circuit diagram showing an embodiment of a light-emitting diode included in a display apparatus and a pixel circuit electrically connected to the light-emitting diode;

FIG. 7 is a schematic cross-sectional view of an embodiment of a display apparatus;

FIG. 8 is a schematic perspective view of an embodiment of an apparatus for manufacturing a display apparatus;

FIG. 9 is a schematic bottom view of an embodiment of a head unit;

FIG. 10 is a schematic cross-sectional view of an embodiment of a head unit, taken along line X-X′ of FIG. 9;

FIG. 11 is a schematic cross-sectional view of an embodiment of a head unit, taken along line X-X′ of FIG. 9; and

FIGS. 12 to 14 are views schematically showing an embodiment of a method for manufacturing a display apparatus.

### DETAILED DESCRIPTION

Reference will now be made in detail to embodiments, illustrative embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to the embodiments, and particular embodiments will be illustrated in the drawings and described in the detailed description. The effects and features of the disclosure, and a method to achieve the same, will become clearer referring to the detailed descriptions below with the drawings. However, the disclosure may be implemented in various forms, not by being limited to the embodiments presented below.

Hereinafter, embodiments will be described, in detail, with reference to the accompanying drawings, and in the description with reference to the drawings, the same or corresponding components are indicated by the same reference numerals and redundant descriptions thereof are omitted.

In the following embodiment, it will be understood that although terms such as “first,” “second” may be used herein to describe various components, these components should not be limited by these terms and these terms are only used to distinguish one component from another.

In the following embodiment, the expression of singularity in the specification includes the expression of plurality unless clearly specified otherwise in context.

In the following embodiment, it will be further understood that the terms “includes,” “has,” “including,” and/or “having” used herein specify the presence of stated features or components, but do not preclude the presence or addition of one or more other features or components.

In the following embodiment, it will be understood that when a layer, region, or component is referred to as being “formed on” another layer, region, or component, the layer, region, or component may be directly or indirectly formed on the other layer, region, or component. That is, for example, intervening layers, regions, or components may be present.

In the following embodiments, when layers, regions, or components are connected to each other, the layers, the regions, or the components may be directly connected to each other, or another layer, another region, or another component may be disposed between the layers, the regions, or the components and thus the layers, the regions, or the components may be indirectly connected to each other. In addition, when layers, regions, or components are electrically connected to each other, the layers, the regions, or the components may be directly electrically connected to each other, or another layer, another region, or another component may be disposed between the layers, the regions, or the components and thus the layers, the regions, or the components may be indirectly electrically connected to each other.

Sizes of components in the drawings may be exaggerated or reduced for convenience of explanation. In other words, because sizes and thicknesses of components in the drawings are arbitrarily illustrated for convenience of explanation, the disclosure are not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

In the following embodiments, the expression such as “A and/or B” may include A, B, or A and B. Furthermore, the expression such as “at least one of A and B” may include A, B, or A and B.

As used herein, when a wiring is referred to as “extending in a first direction or a second direction,” it means that the wiring not only extends in a straight line shape but also extends in a zigzag or in a curve in the first direction or the second direction.

As used herein, “in a plan view” means that an objective portion is viewed from above. In addition, “in a cross-sectional view” means that a cross-section of an objective portion taken vertically is viewed from a lateral side. In the following embodiments, “overlapping” of a first component and a second component means that the first component is disposed above or below the second component.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When an illustrative embodiment may be implemented differently, a predetermined process order may be performed differently from the described order. For example, two consecutively described processes may be performed substantially at the same time or performed in an order opposite to the described order.

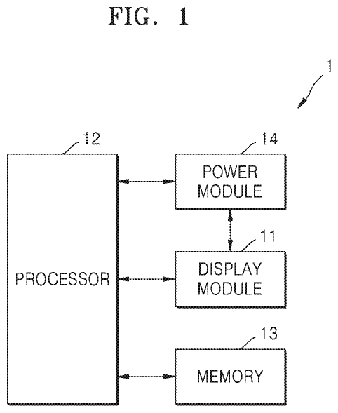

FIG. 1 is a schematic block diagram of an embodiment of an electronic device.

An electronic device 1 in an embodiment may further include a module having another additional function in addition to a display module 11. In an embodiment, as illustrated in FIG. 1, the electronic device 1 in the illustrated embodiment may include the display module 11, a processor 12, a memory 13, and a power module 14, for example.

The processor 12 may control components of the electronic device 1. The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information desired for operations of the processor 12 or the display module 11. When the processor 12 executes an application stored in the memory 13, a data signal and/or an input control signal for an image may be transmitted to the display module 11, and the display module 11 may process the provided signal to output image information.

The power module 14 may include a power supply module such as a power adapter or a battery device, and a power conversion module that converts power supplied by the power supply module to generate power desired for operation of the electronic device 1.

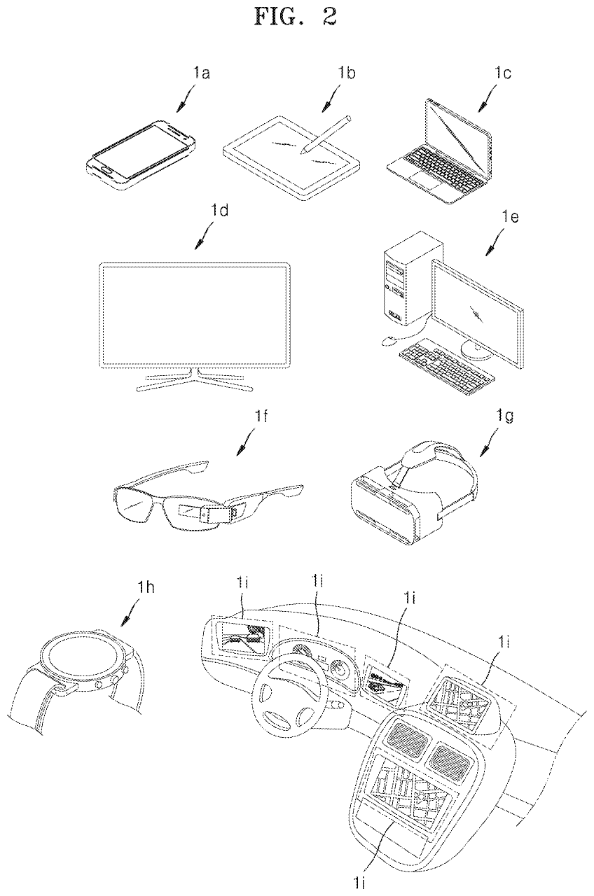

FIG. 2 is schematic diagrams of embodiments of electronic devices.

Referring to FIG. 2, electronic devices 1 including the display module 11 may include image display electronic devices such as a smartphone 1a, a tablet personal computer 1b, a laptop 1c, a television (“TV”) 1d, and a desktop monitor 1e, as well as wearable electronic devices including display modules such as smart glasses 1f, a head mount display 1g, and a smart watch 1h, and vehicle electronic devices 1i including display modules such as an instrument panel of a vehicle, a center information display (“CID”) disposed on a center fascia and a dashboard, and a room mirror display.

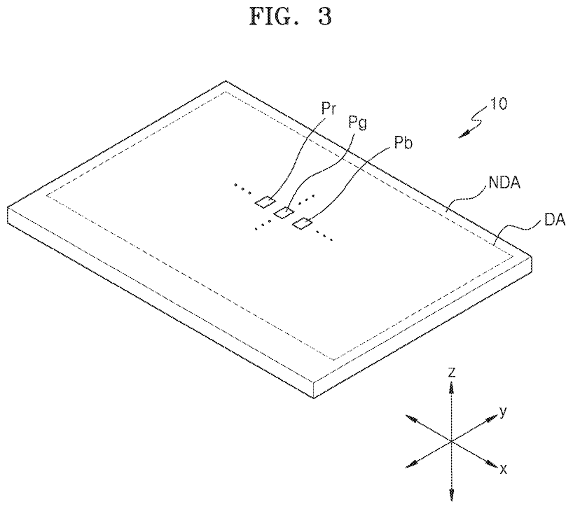

The display module 11 may include a display apparatus 10 (refer to FIG. 3). The display apparatus 10 may be applied to various electronic devices 1. That is, the electronic device 1 may include the display apparatus 10 and may further include a module or device having another additional function in addition to the display apparatus 10. In an embodiment, the electronic device 1 may include the display apparatus 10, the processor 12, the memory 13, and the power module 14, and the display apparatus 10 may be controlled by the processor 12, for example. Hereinafter, the display apparatus 10 will be described.

FIG. 3 is a schematic perspective view of an embodiment of a display apparatus.

Referring to FIG. 3, the display apparatus 10 may include a display area DA and a non-display area NDA outside the display area DA. The display apparatus 10 may provide an image through an array of a plurality of pixels two-dimensionally arranged on an x-y plane in the display area DA. The plurality of pixels include a first pixel, a second pixel, and a third pixel, and hereinafter, for convenience of explanation, the first pixel is a red pixel Pr, the second pixel is a green pixel Pg, and the third pixel is a blue pixel Pb.

The red pixel Pr, the green pixel Pg, and the blue pixel Pb are areas, from which red light, green light, blue light may be emitted, respectively, and the display apparatus 10 may provide an image using light emitted from the pixels.

The non-display area NDA is an area that does not provide an image and may surround an entirety of the display area DA. A driver or a main voltage line for providing an electrical signal or power to pixel circuits may be disposed in the non-display area NDA. The non-display area NDA may include a pad, which may be electrically connected to electronic elements or printed circuit boards.

The display area DA may have a polygonal shape including a rectangle as illustrated in FIG. 1. In an embodiment, the display area DA may have a quadrangular shape, e.g., rectangular shape in which a horizontal length is greater than a vertical length, a rectangular shape in which a horizontal length is less than a vertical length, or a square shape, for example. In an alternative embodiment, the display area DA may have any one of various shapes such as an elliptical and circular shape.

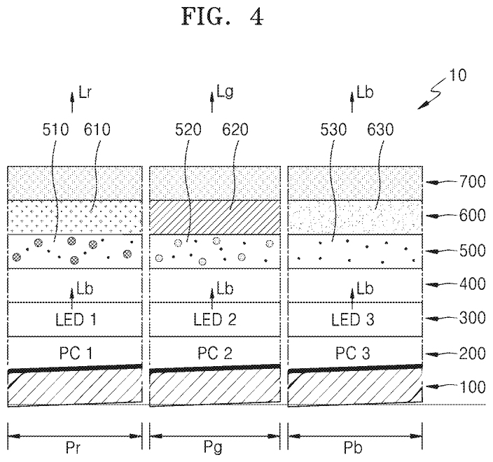

FIG. 4 is a schematic cross-sectional view of an embodiment of pixels of a display apparatus.

Referring to FIG. 4, the display apparatus 10 may include a circuit layer 200 on a substrate 100. The circuit layer 200 includes first to third pixel circuits PC1, PC2, and PC3, and each of the first to third pixel circuits PC1, PC2, and PC3 may be electrically connected to first to third light-emitting diodes LED1, LED2, and LED3 of a light-emitting diode layer 300.

The first to third light-emitting diodes LED1, LED2, and LED3 may include organic light-emitting diodes including an organic material. In an alternative embodiment, the first to third light-emitting diodes LED1, LED2, and LED3 may be inorganic light-emitting diodes including an inorganic material. The inorganic light-emitting diode may include a PN junction diode including inorganic semiconductor-based materials. When a voltage is applied in a forward direction to the PN junction diode, holes and electrons may be injected, and energy generated by the recombination of the holes and electrons may be converted into light energy to emit light of a predetermined color. The inorganic light-emitting diode described above may have a width of several micrometers to several hundred micrometers or several nanometers to several hundred nanometers. In an alternative embodiment, the light-emitting diode LED may be a light-emitting diode including quantum dots. As described above, the emission layer of the light-emitting diode LED may include an organic material, an inorganic material, quantum dots, an organic material and quantum dots, or an inorganic material and quantum dots.

The first to third light-emitting diodes LED1, LED2, and LED3 may emit light of the same color. In an embodiment, light emitted from the first to third light-emitting diodes LED1, LED2, and LED3 (e.g., blue light Lb) may pass through an encapsulation layer 400 on the light-emitting diode layer 300 and then pass through a color conversion-transmission layer 500, for example.

The color conversion-transmission layer 500 may include optical portions that convert or transmit light emitted from the light-emitting diode layer 300 (e.g., blue light Lb) without converting a color thereof. In an embodiment, the color conversion-transmission layer 500 may include color conversion portions that convert light emitted from the light-emitting diode layer 300 (e.g., blue light Lb) into light of another color, and a transmission portion 530 that transmits light emitted from the light-emitting diode layer 300 (e.g., blue light Lb) without color conversion, for example. The color conversion-transmission layer 500 may include a first color conversion portion 510 corresponding to the red pixel Pr, a second color conversion portion 520 corresponding to the green pixel Pg, and a transmission portion 530 corresponding to the blue pixel Pb. The first color conversion portion 510 may convert blue light Lb into red light Lr, and the second color conversion portion 520 may convert blue light Lb into green light Lg. The transmission portion 530 may allow blue light Lb to pass through without conversion.

A color layer 600 may be disposed on the color conversion-transmission layer 500. The color layer 600 may include first to third color filters 610, 620, and 630 of different colors. In an embodiment, the first color filter 610 may be a red color filter, the second color filter 620 may be a green color filter, and the third color filter 630 may be a blue color filter, for example.

The color-converted light and the transmitted light from the color conversion-transmission layer 500 may pass through the first to third color filters 610, 620, and 630 respectively, and thus, color purity may be improved. In addition, the color layer 600 may prevent external light (e.g., light incident toward the display apparatus 10 from outside of the display apparatus 10) from being reflected and being visible to a user.

A light-transmitting base layer 700 may be disposed on the color layer 600. The light-transmitting base layer 700 may include glass or a light-transmitting organic material. In an embodiment, the light-transmitting base layer 700 may include a light-transmitting organic material such as an acrylic resin, for example.

In an embodiment, the light-transmitting base layer 700 is a type of substrate, and after the color layer 600 and the color conversion-transmission layer 500 are formed on the light-transmitting base layer 700, the color conversion-transmission layer 500 may be integrated to face the encapsulation layer 400.

In an alternative embodiment, after the color conversion-transmission layer 500 and the color layer 600 are sequentially formed on the encapsulation layer 400, the light-transmitting base layer 700 may be directly applied and cured on the color layer 600. In an alternative embodiment, the light-transmitting base layer 700 may be seated on the color layer 600 as a hard substrate. Although not shown, another optical film, e.g., an anti-reflection (“AR”) film, may be disposed on the light-transmitting base layer 700.

The display apparatus 10 having the above-described structure may be used in televisions, billboards, movie screens, monitors, tablet personal computers, laptops, etc., but is not limited thereto.

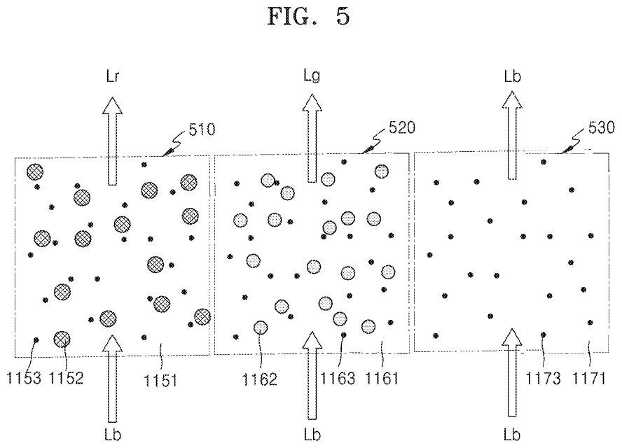

FIG. 5 is a schematic view of optical portions of the color conversion-transmission layer of FIG. 4.

Referring to FIG. 5, the first color conversion portion 510 may convert incident blue light Lb into red light Lr. As illustrated in FIG. 5, the first color conversion portion 510 may include a first photosensitive polymer 1151, first quantum dots 1152 and first scattering particles 1153 dispersed in the first photosensitive polymer 1151.

The first quantum dots 1152 may be excited by blue light Lb and isotropically emit red light Lr having a longer wavelength than a wavelength of the blue light Lb. The first photosensitive polymer 1151 may be an organic material having light transmissivity. The first scattering particles 1153 may scatter blue light Lb that is not absorbed by the first quantum dots 1152 to excite more first quantum dots 1152, thereby increasing color conversion efficiency. The first scattering particles 1153 may be titanium oxide (TiO₂) or metal particles, for example. The first quantum dots 1152 may include or consist of II-VI group compounds, III-V group compounds, IV-VI group compounds, IV group elements, IV group compounds, and combinations thereof.

The second color conversion portion 520 may convert incident blue light Lb into green light Lg. As illustrated in FIG. 5, the second color conversion portion 520 may include a second photosensitive polymer 1161, second quantum dots 1162 and second scattering particles 1163 dispersed in the second photosensitive polymer 1161.

The second quantum dots 1162 may be excited by blue light Lb and isotropically emit green light Lg having a longer wavelength than a wavelength of the blue light Lb. The second photosensitive polymer 1161 may be an organic material having light transmissivity.

The second scattering particles 1163 may scatter blue light Lb that is not absorbed by the second quantum dots 1162 to excite more second quantum dots 1162, thereby increasing color conversion efficiency. The second scattering particles 1163 may be titanium oxide (TiO₂) or metal particles, for example. The second quantum dots 1162 may include or consist of II-VI group compounds, III-V group compounds, IV-VI group compounds, IV group elements, IV group compounds, and combinations thereof.

In an embodiment, the first quantum dots 1152 and the second quantum dots 1162 may be the same material as each other. In this case, a size of the first quantum dots 1152 may be larger than a size of the second quantum dots 1162.

The transmission portion 530 may transmit blue light Lb without converting the blue light Lb incident to the transmission portion 530. As illustrated in FIG. 5, the transmission portion 530 may include a third photosensitive polymer 1171 in which third scattering particles 1173 are dispersed. The third photosensitive polymer 1171 may be an organic material having light transmissivity, such as a silicone resin or an epoxy resin, and may be the same material as that of the first and second photosensitive polymers 1151 and 1161, for example. The third scattering particles 1173 may scatter and emit blue light Lb, and may be the same material as that of the first and second scattering particles 1153 and 1163.

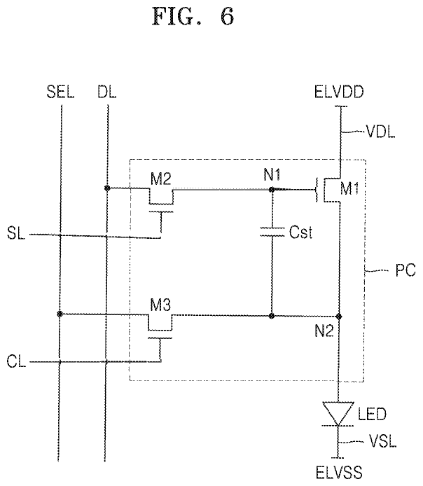

FIG. 6 is an equivalent circuit diagram showing an embodiment of a light-emitting diode included in a display apparatus and a pixel circuit electrically connected to the light-emitting diode.

Referring to FIG. 6, the light-emitting diode LED, for example a first electrode (e.g., an anode) of the light-emitting diode may be connected to a sub-pixel circuit PC, and a second electrode (e.g., a cathode) of the light-emitting diode LED may be connected to a common voltage line VSL that provides a common power voltage ELVSS. The light-emitting diode LED may emit light with luminance corresponding to an amount of current supplied from the sub-pixel circuit PC.

The light-emitting diode LED of FIG. 6 may correspond to each of the first to third light-emitting diodes LED1, LED2, and LED3 illustrated in FIG. 4, and the sub-pixel circuit PC of FIG. 6 may correspond to each of the first to third pixel circuits PC1, PC2, and PC3 illustrated in FIG. 4.

The sub-pixel circuit PC may control an amount of current flowing from a driving power voltage ELVDD to the common power voltage ELVSS via the light-emitting diode LED in response to a data signal. The sub-pixel circuit PC may include a driving transistor M1, a switching transistor M2, a sensing transistor M3, and a storage capacitor Cst.

Each of the driving transistor M1, the switching transistor M2, and the sensing transistor M3 may be an oxide semiconductor thin-film transistor including a semiconductor layer including or consisting of an oxide semiconductor, or a silicon semiconductor thin-film transistor including a semiconductor layer including or consisting of polysilicon. Each of the driving transistor M1, the switching transistor M2, and the sensing transistor M3 may include a source electrode (or a source region) and a drain electrode (or a drain region).

A source electrode (or a source region) of the driving transistor M1 may be connected to a driving voltage line VDL that supplies a driving power voltage ELVDD, and a drain electrode (or a drain region) of the driving transistor M1 may be connected to the first electrode (e.g., an anode) of the light-emitting diode LED. A gate electrode of the driving transistor M1 may be connected to a first node N1. The driving transistor M1 may control an amount of current flowing from the driving power voltage ELVDD through the light-emitting diode LED in response to a voltage of the first node N1. However, positions of the source electrode (or the source region) and the drain electrode (or the drain region) may be interchanged.

The switching transistor M2 may be a switching transistor. A source electrode (or a source region) of the switching transistor M2 may be connected to a data line DL, and a drain electrode (or a drain region) of the switching transistor M2 may be connected to the first node N1. A gate electrode of the switching transistor M2 may be connected to a scan line SL. The switching transistor M2 may be turned on when a scan signal is supplied to the scan line SL to electrically connect the data line DL and the first node N1. However, positions of the source electrode (or the source region) and the drain electrode (or the drain region) may be interchanged.

The sensing transistor M3 may be an initialization transistor and/or a sensing transistor. A dr ain electrode (or a drain region) of the sensing transistor M3 may be connected to a second node N2, and a source electrode (or a source region) may be connected to a sensing line SEL. A gate electrode of the sensing transistor M3 may be connected to a control line CL. However, positions of the source electrode (or the source region) and the drain electrode (or the drain region) may be interchanged.

The storage capacitor Cst may be connected between the first node N1 and the second node N2. In an embodiment, a first capacitor electrode of the storage capacitor Cst may be connected to the gate electrode of the driving transistor M1, and a second capacitor electrode of the storage capacitor Cst may be connected to the first electrode (e.g., an anode) of the light-emitting diode LED, for example.

Although FIG. 6 illustrates the driving transistor M1, the switching transistor M2, and the sensing transistor M3 as n-channel metal-oxide-semiconductor (“NMOS”) transistors, the disclosure is not limited thereto. In an embodiment, at least one of the driving transistor M1, the switching transistor M2, and the sensing transistor M3 may be formed as a p-channel metal-oxide-semiconductor (“PMOS”) transistor, for example.

Although three transistors are illustrated in FIG. 6, the disclosure is not limited thereto. The sub-pixel circuit PC may include four or more transistors.

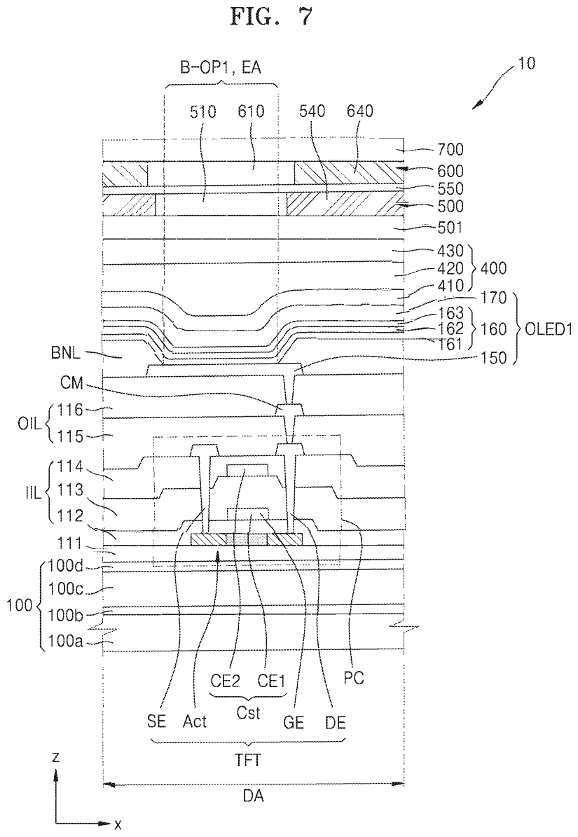

FIG. 7 is a schematic cross-sectional view of an embodiment of a display apparatus.

Referring to FIG. 7, the display apparatus 10 may include a substrate 100, an inorganic insulating layer IIL, an organic insulating layer OIL, a sub-pixel circuit PC, a connection electrode CM, an organic light-emitting diode OLED, a bank layer BNL, an encapsulation layer 400, a color conversion-transmission layer 500, a color layer 600, and a light-transmitting base layer 700. That is, the substrate 100, the inorganic insulating layer IIL, the organic insulating layer OIL, the sub-pixel circuit PC, the connection electrode CM, the organic light-emitting diode OLED, the bank layer BNL, the encapsulation layer 400, the color conversion-transmission layer 500, the color layer 600, and the light-transmitting base layer 700 may be disposed on the display area DA of the display apparatus 10.

The substrate 100 may include a first base layer 100a, a first barrier layer 100b, a second base layer 100c, and a second barrier layer 100d. In an embodiment, the first base layer 100a, the first barrier layer 100b, the second base layer 100c, and the second barrier layer 100d may be sequentially stacked in a thickness direction of the substrate 100.

At least one of the first base layer 100a and the second base layer 100c may include a polymer resin such as polyethersulfone, polyarylate, polyetherimide, polyethylene naphthalate, polyethylene terephthalate, polyphenylene sulfide, polyimide, polycarbonate, cellulose triacetate, or cellulose acetate propionate.

The first barrier layer 100b and the second barrier layer 100d are barrier layers that prevent penetration of external foreign substances, and may be a single layer or multiple layers including inorganic materials such as silicon nitride (SiN_{X}), silicon oxide (SiO₂), and/or silicon oxynitride (SiON).

A buffer layer 111 may be disposed on the substrate 100. The buffer layer 111 may include inorganic insulating materials such as silicon nitride (SiN_{X}), silicon oxynitride (SiON), and silicon oxide (SiO₂), and may be a single layer or multiple layers including the aforementioned inorganic insulating materials.

The inorganic insulating layer IIL may be disposed on the buffer layer 111. The inorganic insulating layer IIL may include a first inorganic insulating layer 112, a second inorganic insulating layer 113, and a third inorganic insulating layer 114.

The sub-pixel circuit PC may be disposed in the display area DA. The sub-pixel circuit PC may include a thin-film transistor TFT and a storage capacitor Cst. The thin-film transistor TFT may include a semiconductor layer Act, a gate electrode GE, a source electrode SE, and a drain electrode DE.

The semiconductor layer Act may be disposed on the buffer layer 111. The semiconductor layer Act may include polysilicon. In an alternative embodiment, the semiconductor layer Act may include amorphous silicon, an oxide semiconductor, or an organic semiconductor. The semiconductor layer Act may include a channel region and a drain region and a source region respectively disposed on opposite sides of the channel region.

A gate electrode GE may be disposed on the semiconductor layer Act. The gate electrode GE may overlap the channel region. The gate electrode GE may include a low-resistance metallic material. The gate electrode GE may include a conductive material including molybdenum (Mo), aluminum (Al), copper (Cu), titanium (Ti), or the like, and may be formed as a multiple layer or a single layer including the aforementioned materials.

A first inorganic insulating layer 112 may be disposed between the semiconductor layer Act and the gate electrode GE. The first inorganic insulating layer 112 may include inorganic insulating materials such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO).

A second inorganic insulating layer 113 may be disposed on the gate electrode GE. The second inorganic insulating layer 113 may be provided to cover the gate electrode GE. The second inorganic insulating layer 113 may include inorganic insulating materials such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO).

An upper electrode CE2 of the storage capacitor Cst may be disposed on the second inorganic insulating layer 113. The upper electrode CE2 may overlap the gate electrode GE which is disposed below the upper electrode CE2. In this case, the gate electrode GE and the upper electrode CE2 overlapping with the second inorganic insulating layer 113 therebetween may form the storage capacitor Cst. That is, the gate electrode GE may function as a lower electrode CE1 of the storage capacitor Cst.

In this way, the storage capacitor Cst and the thin-film transistor TFT may be formed to overlap each other. However, the disclosure is not limited thereto. In an embodiment, the storage capacitor Cst may be formed not to overlap the thin-film transistor TFT, for example. That is, the lower electrode CE1 of the storage capacitor Cst may be provided as a separate component from the gate electrode GE of the thin-film transistor TFT and may be spaced apart from the gate electrode GE of the thin-film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or multiple layers of the aforementioned materials.

A third inorganic insulating layer 114 may be disposed on the upper electrode CE2. The third inorganic insulating layer 114 may cover the upper electrode CE2. The third inorganic insulating layer 114 may include inorganic insulating materials such as silicon oxide (SiO₂), silicon nitride (SiN_{X}), silicon oxynitride (SiON), aluminum oxide (Al₂O₃), titanium oxide (TiO₂), tantalum oxide (Ta₂O₅), hafnium oxide (HfO₂), or zinc oxide (ZnO). The third inorganic insulating layer 114 may be a single layer or multiple layers including the aforementioned inorganic insulating materials.

The drain electrode DE and the source electrode SE may each be disposed on the third inorganic insulating layer 114. The drain electrode DE and the source electrode SE may each be connected to the semiconductor layer Act through contact holes defined in the first inorganic insulating layer 112, the second inorganic insulating layer 113, and the third inorganic insulating layer 114. The drain electrode DE and the source electrode SE may include materials having good conductivity. The drain electrode DE and the source electrode SE may include a conductive material including molybdenum (Mo), aluminum (Al), copper (Cu), titanium (Ti), or the like, and may be formed as a multiple layer or a single layer including the aforementioned materials. In an embodiment, the drain electrode DE and the source electrode SE may have a multilayer structure of Ti/Al/Ti, for example.

The organic insulating layer OIL may be disposed on the inorganic insulating layer IIL. The organic insulating layer OIL may include a first organic insulating layer 115 and a second organic insulating layer 116. Although FIG. 7 illustrates that two organic insulating layers OIL are provided, the disclosure is not limited thereto. The organic insulating layers OIL may be provided as three or four layers.

The first organic insulating layer 115 may cover the drain electrode DE and the source electrode SE. The first organic insulating layer 115 may include organic insulating materials such as general polymers like Polymethylmethacrylate (“PMMA”) or Polystyrene (“PS”), polymer derivatives having phenolic groups, acrylic polymers, imide polymers, aryl ether polymers, amide polymers, fluorinated polymers, p-xylene polymers, vinyl alcohol polymers, and blends thereof.

A connection electrode CM may be disposed on the first organic insulating layer 115. In this case, the connection electrode CM may be connected to the drain electrode DE or the source electrode SE through a contact hole of the first organic insulating layer 115. The connection electrode CM may include a material having good conductivity. The connection electrode CM may include a conductive material including molybdenum (Mo), aluminum (Al), copper (Cu), titanium (Ti), or the like, and may be formed as a multiple layer or a single layer including the aforementioned materials. In an embodiment, the connection electrode CM may have a multilayer structure of Ti/Al/Ti, for example.

A second organic insulating layer 116 may be disposed on the connection electrode CM. The second organic insulating layer 116 may cover the connection electrode CM. The second organic insulating layer 116 may be provided with the same material as that of the first organic insulating layer 115 or may be provided with a different material.

A light-emitting diode may be disposed on the second organic insulating layer 116. In an embodiment, an organic light-emitting diode OLED may be disposed on the second organic insulating layer 116, for example. In an alternative embodiment, although not shown, an inorganic light-emitting diode may be disposed on the second organic insulating layer 116.

A first electrode 150 of the light-emitting diode may be disposed on the second organic insulating layer 116. In this regard, FIG. 7 illustrates a first electrode 150 of a first organic light-emitting diode OLED1. In this case, the first electrode 150 may be an anode.

The first electrode 150 may include transparent conductive oxides such as indium tin oxide (“ITO”), indium zinc oxide (“IZO”), zinc oxide (ZnO), indium oxide (In₂O₃), indium gallium oxide (“IGO”), and aluminum zinc oxide (“AZO”). In an alternative embodiment, the first electrode 150 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or compounds thereof. In an alternative embodiment, the first electrode 150 may further include a layer including or consisting of ITO, IZO, ZnO, or In₂O₃ above/below the aforementioned reflective layer. In an embodiment, the first electrode 150 may have a three-layer structure in which an ITO layer, a silver (Ag) layer, and an ITO layer are stacked, for example.

The bank layer BNL may cover an edge of the first electrode 150, and a first bank opening B-OP1 that overlaps a central portion of the first electrode 150 (or exposes at least a portion of the first electrode 150) may be defined in the bank layer BNL. The bank layer BNL may include an organic insulating material such as polyimide.

An intermediate layer 160 may contact the first electrode 150 through the first bank opening B-OP1 of the bank layer BNL. A stacked structure of the first electrode 150, the intermediate layer 160, and a second electrode 170 disposed in the first bank opening B-OP1 may emit light of a preset color. The first bank opening B-OP1 of the bank layer BNL may correspond to an emission area EA where light is emitted. In an embodiment, a size (or width) of the first bank opening B-OP1 of the bank layer BNL may correspond to a size (or width) of the emission area EA, for example.

The intermediate layer 160 may include an emission layer 162. The emission layer 162 may include a relatively high molecular weight organic material or a relatively low molecular weight organic material that emits light of a preset color. As described above with reference to FIG. 4, when the light-emitting diode layer 300 (refer to FIG. 4) emits blue light, the emission layer 162 may include a relatively high molecular weight organic material or a relatively low molecular weight organic material that emits blue light.

In an embodiment, the intermediate layer 160 may include at least one functional layer disposed above or below the emission layer 162. In an embodiment, as illustrated in FIG. 7, the intermediate layer 160 may include a first functional layer 161 disposed below the emission layer 162 and/or a second functional layer 163 disposed above the emission layer 162, for example. The first functional layer 161 may be disposed between the first electrode 150 and the emission layer 162, and the second functional layer 163 may be disposed between the emission layer 162 and a second electrode 170 to be described below.

The first functional layer 161 may include a hole transport layer (“HTL”) and/or a hole injection layer (“HIL”). The second functional layer 163 may include an electron transport layer (“ETL”) and/or an electron injection layer (“EIL”).

The second electrode 170 may be disposed on the intermediate layer 160. The second electrode 170 may be a cathode, for example. The second electrode 170 may include or consist of a conductive material having a relatively low work function. In an embodiment, the second electrode 170 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or alloys thereof, for example. In an alternative embodiment, the second electrode 170 may further include a layer such as ITO, IZO, ZnO, or In2O3 on the (semi)transparent layer including the aforementioned materials.

In an embodiment, the encapsulation layer 400 may be disposed on the second electrode 170. The encapsulation layer 400 may include at least one inorganic encapsulation layer and at least one organic encapsulation layer. In an embodiment, the encapsulation layer 400 may include a first inorganic encapsulation layer 410, an organic encapsulation layer 420, and a second inorganic encapsulation layer 430. The organic encapsulation layer 420 may be disposed between the first inorganic encapsulation layer 410 and the second inorganic encapsulation layer 430.

The first and second inorganic encapsulation layers 410 and 430 may each include one or more inorganic insulating materials. The inorganic insulating material may include aluminum oxide, titanium oxide, tantalum oxide, hafnium oxide, zinc oxide, silicon oxide, silicon nitride, and/or silicon oxynitride.

The organic encapsulation layer 420 may include a polymer-based material. Polymer-based materials may include acrylic resins, epoxy resins, polyimide, and polyethylene. In an embodiment, the organic encapsulation layer 420 may include an acrylic resin, such as polymethyl methacrylate or polyacrylic acid, for example. The organic encapsulation layer 420 may be formed by curing a monomer or applying a polymer.

An intermediate material layer 501 may be disposed on the encapsulation layer 400. The intermediate material layer 501 may include an inorganic insulating material and/or an organic insulating material. The color conversion-transmission layer 500 may be disposed on the intermediate material layer 501. In this regard, FIG. 7 illustrates a light-blocking portion 540 of the color conversion-transmission layer 500 and a first color conversion portion 510 disposed in an opening area defined by the light-blocking portion 540.

A barrier layer 550 may be formed on the color conversion-transmission layer 500. The barrier layer 550 may include inorganic insulating materials such as silicon oxide, silicon nitride, and/or silicon oxynitride.

The color layer 600 may be disposed above the color conversion-transmission layer 500. In this regard, FIG. 5 illustrates a light-blocking portion 640 of the color layer 600 and a first color filter 610 disposed in an opening area defined by the light-blocking portion 640. The light-blocking portion 540 of the color conversion-transmission layer 500 (hereinafter referred to as a first light-blocking portion) and the light-blocking portion 640 of the color layer 600 (hereinafter referred to as a second light-blocking portion) may be disposed to overlap each other.

The first light-blocking portion 540 and the second light-blocking portion 640 may each include a light-blocking material. In an embodiment, the first light-blocking portion 540 and the second light-blocking portion 640 may each include an organic material having a preset color such as black, for example. In an embodiment, the first light-blocking portion 540 and the second light-blocking portion 640 may each include a polyimide (“PI”)-based binder and a pigment in which red, green, and blue are mixed, for example. In an alternative embodiment, the first light-blocking portion 540 and the second light-blocking portion 640 may each include a cardo-based binder resin and a combination of lactam black pigment and blue pigment. In an alternative embodiment, the first light-blocking portion 540 and the second light-blocking portion 640 may each include carbon black.

In an embodiment, the first light-blocking portion 540 and the second light-blocking portion 640 may include the same material as each other. In an alternative embodiment, the second light-blocking portion 640 may have a structure in which at least two or more color filters forming the color layer 600 are overlapped. In an embodiment, the second light-blocking portion 640 may not include the aforementioned light-blocking material and may have a structure in which two or more color filter materials selected from the first to third color filters 610, 620, and 630 (refer to FIG. 2) are stacked, for example.

The light-transmitting base layer 700 may include glass or a light-transmitting organic material. In an embodiment, the light-transmitting base layer 700 may include a light-transmitting organic material such as an acrylic resin, for example.

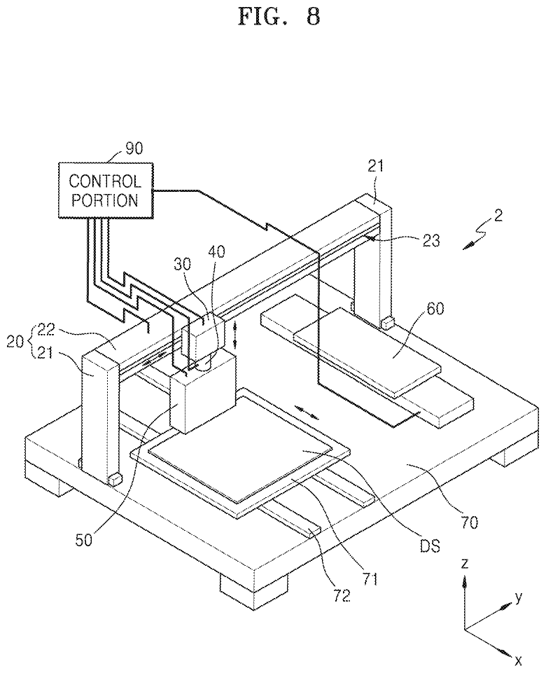

FIG. 8 is a schematic perspective view of an embodiment of an apparatus for manufacturing a display apparatus.

Referring to FIG. 8, the apparatus 2 for manufacturing a display apparatus in an embodiment may be used to manufacture the display apparatus 10 described above. In an embodiment, the apparatus 2 for manufacturing a display apparatus may jet ink to stack at least one of a plurality of layers of the display apparatus 10, for example. In an embodiment, the apparatus 2 for manufacturing a display apparatus may be used to stack the color conversion-transmission layer 500 or may be used to stack the color layer 600, for example. In an embodiment, the apparatus 2 for manufacturing a display apparatus may jet ink to form the first color conversion portion 510 or may jet ink to form the first color filter 610, for example. In an alternative embodiment, the apparatus 2 for manufacturing a display apparatus may be used to apply an adhesive material for attaching the light-transmitting base layer 700 on the color layer 600. However, the disclosure is not limited thereto, and of course, the apparatus 2 for manufacturing a display apparatus may be used to jet various inks.

The apparatus 2 for manufacturing a display apparatus may include a support portion 70, a gantry 20, a first moving portion 30, a second moving portion 40, a head unit 50, a maintenance portion 60, and a control portion 90.

The support portion 70 is an element on which other components are seated, and in an embodiment, may have a plane defined by a first direction (e.g., an x direction in FIG. 8) and a second direction (e.g., a y direction in FIG. 8) intersecting the first direction. Additionally, in an embodiment, the support portion 70 may have a quadrangular plane as illustrated in FIG. 8, but the disclosure is not limited thereto and may have any one of various shapes such as polygonal or circular shapes.

A stage 71 may be further provided on the support portion 70. The stage 71 may be disposed on the support portion 70 and may have a plane defined by the first direction and the second direction. A display substrate DS may be seated on the stage 71, and the stage 71 may include an alignment mark (not shown) for aligning the display substrate DS. Here, the display substrate DS is a part of a display apparatus being manufactured and may be a target to which the head unit 50 discharges ink. That is, the discharged ink may be attached to the display substrate DS to form a partial layer of the display apparatus. The stage 71 may provide a working area for an inkjet printing process.

A guide portion 72 may be further provided between the support portion 70 and the stage 71. The guide portion 72 may be disposed on the support portion 70 and may be spaced apart from each other below the stage 71. In an embodiment, two guide portions 72 may be provided and may be spaced apart in the second direction to be next (adjacent) to opposite sides of the stage 71, for example. Each guide portion 72 may extend along the first direction, and an extension length of each guide portion 72 in the first direction may be greater than a length of the stage 71 in the first direction.

The guide portion 72 may guide the stage 71 to enable linear movement along an extension direction of the guide portion 72. The guide portion 72 may include a linear motion rail, for example.

In an embodiment, the stage 71 may linearly reciprocate along the guide portion 72. The stage 71 may move linearly manually or may automatically move linearly by including a motor cylinder or the like. In an embodiment, the stage 71 may automatically move linearly by including a linear motion block that moves along a linear motion rail, for example.

The gantry 20 may be disposed on the support portion 70 and may include a vertical member 21 and a horizontal member 22. Although FIG. 6 illustrates that the vertical member 21 and the horizontal member 22 have a quadrangular bar shape, e.g., rectangular bar shape, the shapes of the vertical member 21 and the horizontal member 22 are not limited thereto.

The vertical members 21 of the gantry 20 may extend in a third direction (e.g., a z direction in FIG. 8) that intersects the first direction and the second direction, respectively. The vertical members 21 may be provided, e.g., in two and may be disposed on opposite sides with the stage 71 therebetween.

The horizontal member 22 of the gantry 20 may extend along the second direction between the vertical members 21. Opposite ends of the horizontal member 22 may be connected to upper portions of each of the vertical members 21. A first groove area 23 extending in an extension direction of the horizontal member 22, that is, in the second direction may be defined in The horizontal member 22. The first groove area 23 may be defined in one side of the horizontal member 22. In an embodiment, the first groove area 23 may be defined in a surface of the horizontal member 22 facing the first direction, for example. The first groove area 23 may guide the first moving portion 30 to enable linear reciprocating movement along an extension direction of the first groove area 23.

Although the above description has focused on the gantry 20 being fixed on the support portion 70 and the stage 71 moving in the first direction across the horizontal member 22 of the gantry 20, the disclosure is not limited thereto. In another embodiment, of course, the stage 71 may be fixed on the support portion 70 and the gantry 20 may move in the first direction on the support portion 70. In other words, the gantry 20 and the stage 71 may move relative to each other in the first direction. Hereinafter, for convenience of explanation, since the gantry 20 and the stage 71 move relative to each other in the first direction, the description will be made assuming that the stage 71 moves in the first direction.

The first moving portion 30 may move linearly along the second direction. The first moving portion 30 may be movably connected to one side of the horizontal member 22 of the gantry 20. In an embodiment, the first moving portion 30 may be disposed on a surface of the horizontal member 22 where the first groove area 23 is defined, for example. The first moving portion 30 may linearly reciprocate in the second direction along the first groove area 23. In an embodiment, the first moving portion 30 may include a linear motor or the like.

In an embodiment, the second moving portion 40 may be disposed on one side of the first moving portion 30 and may linearly reciprocate along the third direction. In an embodiment, the second moving portion 40 may be disposed on a bottom surface of the first moving portion 30, for example. Here, the bottom surface of the first moving portion 30 may be a surface of the first moving portion 30 facing the stage 71. In an embodiment, the second moving portion 40 may include a pneumatic cylinder or the like. Additionally, the second moving portion 40 may rotationally move about an axis extending in the third direction. For this purpose, the second moving portion 40 may include an electric motor, a pneumatic motor, or the like.

In an embodiment, the head unit 50 may be disposed on a bottom surface of the second moving portion 40. The head unit 50 may move together as the first moving portion 30 and the second moving portion 40 move. That is, the first moving portion 30 may transport the head unit 50 along the second direction, and the second moving portion 40 may transport the head unit 50 along the third direction. In an embodiment, a movement range of the head unit 50 may be substantially the same as an area of the support portion 70, for example. The head unit 50 may also be rotated about an axis extending in the third direction by the second moving portion 40.

The head unit 50 may discharge ink droplets toward the display substrate DS. In this case, in an embodiment, the ink may be a relatively high molecular weight or relatively low molecular weight organic material corresponding to an emission layer of an organic light-emitting display device. In another embodiment, the ink may be liquid crystal, an alignment liquid, or a red, green, or blue liquid in which pigment particles are mixed in a solvent. In another embodiment, the ink may include a solution including or consisting of inorganic particles such as quantum dot materials, but is not limited to the aforementioned examples.

The maintenance portion 60 may be disposed on the support portion 70 and may be spaced apart from the stage 71 in the second direction. The maintenance portion 60 may be disposed between the two vertical members 21 of the gantry 20. The maintenance portion 60 may be a stage for maintenance of the head unit 50. In an embodiment, the maintenance portion 60 may include a unit for removing ink remaining in the head unit 50. By removing ink remaining in the head unit 50, ink discharge failure may be prevented. The head unit 50 may move in the second direction through the horizontal member 22 of the gantry 20 and may be moved to the maintenance portion 60.

The control portion 90 may be electrically connected to the stage 71, the guide portion 72, the first moving portion 30, the second moving portion 40, and the head unit 50. The control portion 90 may control a position and operation of each component. Additionally, of course, the control portion 90 may be electrically connected to the maintenance portion 60 to control an operation of the maintenance portion 60. The control portion 90 may be a hardware component such as a circuitry that performs a predetermined function. The hardware component may include a field-programmable gate array (“FPGA”) or an application-specific integrated circuit (“ASIC”), for example.

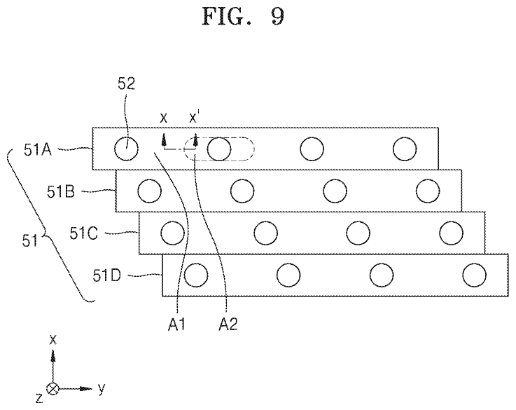

FIG. 9 is a schematic bottom view of an embodiment of a head unit.

Referring to FIG. 9, the head unit 50 may include a body portion 51 and a nozzle 52. The body portion 51 may be connected to the second moving portion 40 and may linearly move in the second direction (e.g., y direction) through the horizontal member 22 of the gantry 20. Additionally, of course, the body portion 51 may linearly move in the third direction through the second moving portion 40. Additionally, the body portion 51 may be disposed to face the display substrate DS and may move relative to the display substrate DS in the first direction (e.g., x direction). In an embodiment, the stage 71 on which the display substrate DS is disposed may be moved in the first direction, or the stage 71 on which the display substrate DS is disposed may be fixed and the gantry 20 may be moved in the first direction, for example.

In an embodiment, the body portion 51 may extend lengthwise along the second direction (e.g., y direction). Additionally, in an embodiment, a plurality of body portions 51 may be provided, and in this case, the plurality of body portions 51 may be disposed side by side in the first direction (e.g., x direction). Although the drawings illustrate that four body portions 51 are provided, the disclosure is not limited thereto. In another embodiment, the body portions 51 may be provided as four or fewer, or four or more.

A plurality of nozzles 52 may be disposed in each of the plurality of body portions 51. The plurality of nozzles 52 may discharge ink accommodated in the body portion 51. Although the drawings illustrate that four nozzles 52 are disposed in each body portion 51, the disclosure is not limited thereto. In another embodiment, of course, four or more, or four or fewer nozzles 52 may be disposed in each body portion 51.

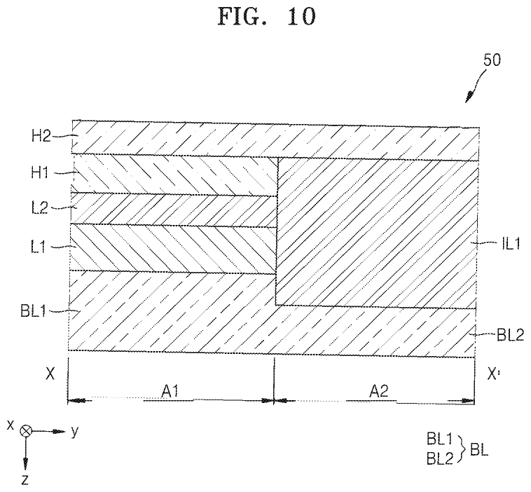

FIG. 10 is a schematic cross-sectional view of an embodiment of a head unit, taken along line X-X′ of FIG. 9.

Referring to FIG. 10, the head unit 50 may include a first area A1 and a second area A2. In an embodiment, the first area A1 may be a normal (non-damaged) area, and the second area A2 may be a damaged area. The head unit 50 may be moved to the maintenance portion 60 for maintenance as described above, and ink remaining in the nozzle 52 of the head unit 50 may be removed. In an embodiment, the maintenance portion 60 may include a wiper, and remaining ink in the head unit 50 may be removed through blotting of the wiper. In this case, a surface of the head unit 50, e.g., a surface of the body portion 51, may be damaged during the blotting process, e.g., the surface may be worn. Accordingly, a first liquid-repelling layer formed on the surface of the body portion 51 may be removed in a partial area. It will be understood that an area where the surface of the body portion 51 is damaged may be defined as the second area A2, and a normal (non-damaged) area where the surface of the body portion 51 is not damaged may be defined as the first area A1. Additionally, it will be understood that the second area A2 may be an area including the nozzle 52, specifically an area in which a nozzle hole through which ink is sprayed is defined, or an area next (adjacent) to the nozzle hole.

Upon examining a surface of the head unit 50, e.g., a surface of the body portion 51, in the first area A1, in an embodiment, the head unit 50 may include a base layer BL in the first area A1. In the description, a portion of the base layer in the first area A1 may be also referred to as a first base layer portion BL1. In an embodiment, the base layer BL may include polyimide. The base layer BL may form an outer appearance of the body portion 51. A thickness of the base layer BL may be about 70 micrometers (μm) to about 80 μm.

A first layer L1 may be disposed on the base layer BL. In this case, an upper portion of the base layer BL may mean a direction toward an outer side from the base layer BL. In an embodiment, the first layer L1 may include an organic material. A thickness of the first layer L1 may be about 10 nanometers (nm) to about 15 nm.

A second layer L2 may be disposed on the first layer L1. In an embodiment, the second layer L2 may include silicon dioxide (SiO₂). A thickness of the second layer L2 may be about 3 nm to about 7 nm.

A first liquid-repelling layer H1 may be disposed on the second layer L2. The first liquid-repelling layer H1 may include a hydrophobic material. The first liquid-repelling layer H1 may prevent spreading of ink during ink discharge and improve printing quality due to liquid-repelling characteristics.

Additionally, although the illustrated embodiment has been described with respect to the first layer L1 and the second layer L2, the disclosure is not limited thereto. In some embodiments, additional layers such as a third layer and a fourth layer may be disposed between the first liquid-repelling layer H1 and the base layer BL, or at least one of the first layer L1 and the second layer L2 may be omitted.

Upon examining at a surface of the head unit 50, e.g., a surface of the body portion 51, in the second area A2, in an embodiment, the head unit 50 may include a base layer BL in the second area A2. In the description, a portion of the base layer in the second area A2 may be also referred to as a second base layer portion BL2. In an embodiment, the base layer BL may include polyimide. That is, the base layer BL may be integrally formed (or unitary) across the first area A1 and the second area A2. In this case, in an embodiment, a thickness of the base layer BL (or the second base layer portion BL2) in the second area A2 may be less than a thickness of the base layer BL (or the first base layer portion BL1) in the first area A1. This may be due to abrasion of a portion of the base layer BL as the surface of the body portion 51 is damaged.

A first inorganic layer IL1 may be disposed on the base layer BL. In an embodiment, the first inorganic layer IL1 may be formed to have a thickness corresponding to the first liquid-repelling layer H1 of the first area A1. In an embodiment, an upper surface of the first inorganic layer IL1 may be disposed on a same plane as an upper surface of the first liquid-repelling layer H1. That is, a sum of thicknesses of the first layer L1, the second layer L2, and the first liquid-repelling layer H1 in the first area A1 may be equal to or less than a thickness of the first inorganic layer IL1 in the second area A2. In an embodiment, the first inorganic layer IL1 may have substantially low adhesion to the first liquid-repelling layer H1. In an embodiment, the first inorganic layer IL1 may include silicon dioxide (SiO2), for example.

However, it will be understood that the disclosure is not necessarily limited thereto. in an embodiment, a thickness of the base layer BL (or the second base layer portion BL2) in the second area A2 may be the same as a thickness of the base layer BL (or the first base layer portion BL1) in the first area A1, for example. Additionally, a first layer L1 may be disposed on the base layer BL (or the second base layer portion BL2) in the second area A2. In this case, a thickness of the first layer L1 in the second area A2 may be less than a thickness of the first layer L1 in the first area A1. This may be due to abrasion of a portion of the first layer L1 as the surface of the body portion 51 is damaged. In this case, it will be understood that the first inorganic layer IL1 may be disposed on the first layer L1.

In an embodiment, a thickness of the base layer BL (or the second base layer portion BL2) in the second area A2 may be the same as a thickness of the base layer BL (or the first base layer portion BL1) in the first area A1. A first layer L1 may be disposed on the base layer BL (or the second base layer portion BL2) in the second area A2, and a thickness of the first layer L1 in the second area A2 may be the same as a thickness of the first layer L1 in the first area A1. Additionally, a second layer L2 may be disposed on the first layer L1 in the second area A2. In this case, a thickness of the second layer L2 in the second area A2 may be less than a thickness of the second layer L2 in the first area A1. This may be due to abrasion of a portion of the second layer L2 as the surface of the body portion 51 is damaged. In this case, it will be understood that the first inorganic layer IL1 may be disposed on the second layer L2.

In an embodiment, a thickness of the base layer BL (or the second base layer portion BL2) in the second area A2 may be the same as a thickness of the base layer BL1 in the first area A1. A first layer L1 may be disposed on the base layer BL2 in the second area A2, and a thickness of the first layer L1 in the second area A2 may be the same as a thickness of the first layer L1 in the first area A1. A second layer L2 may be disposed on the first layer L1 in the second area A2, and a thickness of the second layer L2 in the second area A2 may be the same as a thickness of the second layer L2 in the first area A1. Additionally, a first liquid-repelling layer H1 may be disposed on the second layer L2 in the second area A2. In this case, a thickness of the first liquid-repelling layer H1 in the second area A2 may be less than a thickness of the first liquid-repelling layer H1 in the first area A1. This may be due to abrasion of a portion of the first liquid-repelling layer H1 as the surface of the body portion 51 is damaged. In this case, it will be understood that the first inorganic layer IL1 may be disposed on the first liquid-repelling layer H1.

Hereinafter, for convenience of explanation, as illustrated in FIG. 10, description will be made focusing on a case where the surface of the body portion 51 is worn and removed to a portion of the base layer BL.

A second liquid-repelling layer H2 may be disposed across the entirety of the first area A1 and second area A2. Specifically, in the first area A1, the second liquid-repelling layer H2 may be disposed on the first liquid-repelling layer H1. In the second area A2, the second liquid-repelling layer H2 may be disposed on the first inorganic layer IL1. In this case, the second liquid-repelling layer H2 may continuously cover the surface of the head unit 50 in the first area A1 and the second area A2. That is, the first liquid-repelling layer H1 may be disposed under the second liquid-repelling layer H2 in the first area A1, and the first inorganic layer IL1 may be disposed under the second liquid-repelling layer H2 in the second area A2. In an embodiment, the second liquid-repelling layer H2 may have a thickness of about 8 nm to about 10 nm.

In an embodiment, the second liquid-repelling layer H2 may include a hydrophobic material. Additionally, in an embodiment, the second liquid-repelling layer H2 may include a different material from a material of the first liquid-repelling layer H1. The second liquid-repelling layer H2 may prevent spreading of ink during ink discharge and improve printing quality due to liquid-repelling characteristics. In particular, when the surface of the head unit 50 is damaged during maintenance of the head unit 50, e.g., when the first liquid-repelling layer H1 is damaged, liquid-repelling characteristics may be maintained through the second liquid-repelling layer H2. Additionally, because a step difference on the surface of the damaged head unit 50 is compensated through the first inorganic layer IL1 disposed under the second liquid-repelling layer H2, a planarized surface of the head unit 50 may be maintained, and printing quality may be improved.

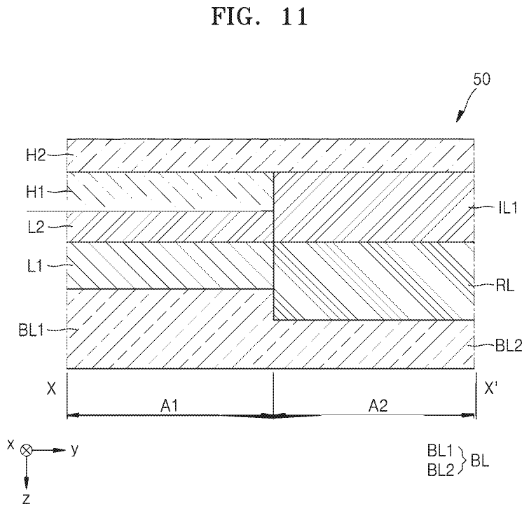

FIG. 11 is a schematic cross-sectional view of an embodiment of a head unit, taken along line X-X′ of FIG. 9. Since the head unit in the illustrated embodiment is similar to the head unit described above, only differences will be described below.

Referring to FIG. 11, the head unit 50 in the second area A2 may further include a reinforcement layer RL. The reinforcement layer RL may improve durability in the second area A2.

The reinforcement layer RL may be disposed between the first inorganic layer IL1 and the base layer BL. That is, the reinforcement layer RL may be disposed on the base layer BL, and the first inorganic layer IL1 may be disposed on the reinforcement layer RL. In this case, as described above, in an embodiment, an upper surface of the first inorganic layer IL1 may be disposed on a same plane as an upper surface of the first liquid-repelling layer H1. That is, a sum of thicknesses of the first layer L1, the second layer L2, and the first liquid-repelling layer H1 in the first area A1 may be equal to or less than a sum of thicknesses of the first inorganic layer IL1 and the reinforcement layer RL in the second area A2. In an embodiment, a thickness of the reinforcement layer RL may be about 95 nm to about 105 nm, and a thickness of the first inorganic layer IL1 may be about 125 nm to about 135 nm.

In an embodiment, the reinforcement layer RL may have substantially low adhesion to the first liquid-repelling layer H1. In an embodiment, the reinforcement layer RL may include aluminum oxide (Al₂O₃). In another embodiment, the reinforcement layer RL may include a metallic material. In an embodiment, the metallic material may include magnesium (Mg) and silver (Ag), or may include aluminum (Al), for example.

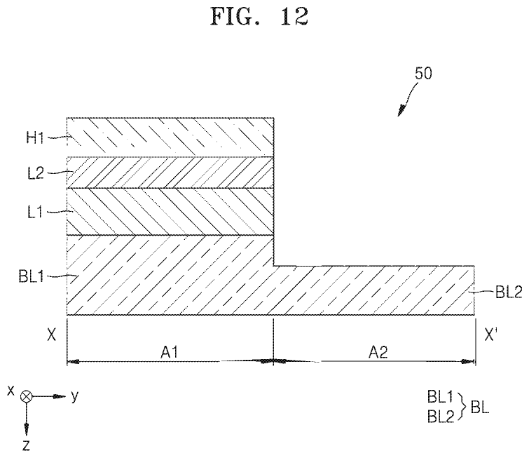

FIGS. 12 to 14 are views schematically showing an embodiment of a method for manufacturing a display apparatus.

The method for manufacturing a display apparatus in the illustrated embodiment may use the apparatus 2 for manufacturing a display apparatus described above, but the disclosure is not necessarily limited thereto.

Referring to FIG. 12, the head unit 50 including the first area A1 and the second area A2 may be prepared. In an embodiment, the first area A1 may be a normal (non-damaged) area on the surface of the head unit 50, and the second area A2 may be a damaged area on the surface of the head unit 50. As described above, the second area A2 may be formed as the surface of the head unit 50 is worn during a blotting process of a wiper of the maintenance portion 60. In an embodiment, in the second area A2, the surface of the head unit 50 may have the first liquid-repelling layer H1, the second layer L2, and the first layer L1 worn and removed, for example. In an alternative embodiment, in the second area A2, the surface of the head unit 50 may have at least a portion of the first liquid-repelling layer H1, the second layer L2, and the first layer L1 worn and removed. In an alternative embodiment, in the second area A2, the surface of the head unit 50 may be worn and removed to a portion of the base layer BL. Hereinafter, for convenience of explanation, description will be made focusing on a case where the head unit 50 in the second area A2 is worn to a portion of the base layer BL and includes only the base layer BL.

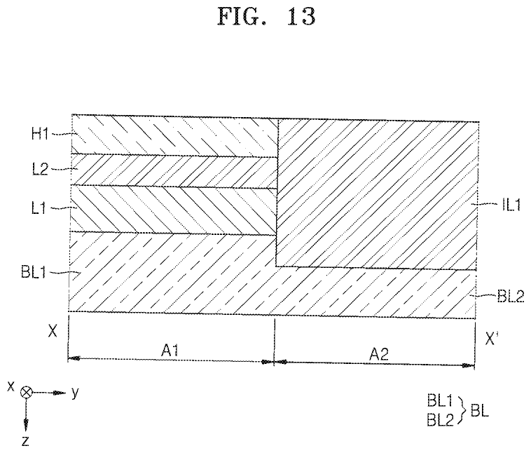

Referring to FIG. 13, an inorganic material may be deposited on the surface of the head unit 50. In an embodiment, the inorganic material may be deposited by a physical vapor deposition method.

In an embodiment, the inorganic material may include silicon dioxide (SiO₂). The inorganic material including silicon dioxide may not adhere to the first liquid-repelling layer H1, and accordingly, the inorganic material may not be deposited on the first liquid-repelling layer H1. That i s, when depositing an inorganic material on the entirety of the surface of the head unit 50, the inorganic material may not be deposited on the first area A1 where the first liquid-repelling layer H1 is present, and the inorganic material may be deposited on the second area A2 where the first liquid-repelling layer H1 is not present. In this case, in an embodiment, the inorganic material may be deposited to a same plane as an upper surface of the first liquid-repelling layer H1 of the first area A1. In other words, the inorganic material may cover a reduced thickness where the surface of the head unit 50 is damaged. The inorganic material may be deposited to form the first inorganic layer IL1 described above.

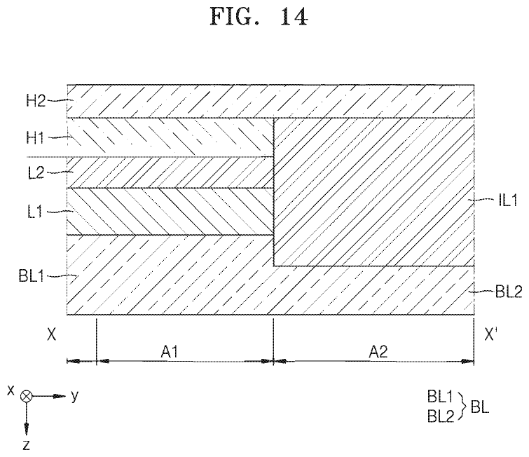

Referring to FIG. 14, the second liquid-repelling layer H2 may be deposited on the surface of the head unit 50. The second liquid-repelling layer H2 may be formed to continuously cover the surface of the head unit 50 across the first area A1 and the second area A2. That is, in the first area A1, the second liquid-repelling layer H2 may be formed to cover the first liquid-repelling layer H1, and in the second area A2, the second liquid-repelling layer H2 may be formed to cover the first inorganic layer IL1. In other words, in the first area A1, the second liquid-repelling layer H2 may be disposed to overlap the first liquid-repelling layer H1, and in the second area A2, the second liquid-repelling layer H2 may be disposed to overlap the first inorganic layer IL1.

By embodiments, a surface of the damaged head unit 50 may be easily reformed. By embodiments, to restore the surface of the damaged head unit 50, the first liquid-repelling layer H1 does not need to be O₂ ashed, and an inorganic material may be deposited on the entirety of the surface of the head unit 50. The inorganic material may not be deposited on the first liquid-repelling layer H1 in the first area A1 and may be deposited only on the second area A2, and accordingly, a surface step may not be formed even when reforming the surface of the head unit 50.

By embodiments, the head unit may not have a surface step, and printing quality may be improved.

The effects of the disclosure are not limited to the effects mentioned above, and other effects not mentioned will be clearly understood by those skilled in the art from the description of the claims.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. An apparatus for manufacturing a display apparatus, the apparatus comprising:
a stage on which a display substrate is seated; and
a head unit facing the stage and configured to spray ink onto the display substrate, the head unit including:
a first area; and
a second area next to the first area,
a second liquid-repelling layer continuously covering a surface of the head unit in the first area and the second area; and
a first liquid-repelling layer disposed under the second liquid-repelling layer in the first area.

2. The apparatus of claim 1, wherein the head unit in the second area further includes a first inorganic layer disposed under the second liquid-repelling layer.

3. The apparatus of claim 2, wherein an upper surface of the first liquid-repelling layer and an upper surface of the first inorganic layer are disposed on a same plane.

4. The apparatus of claim 1, wherein the second liquid-repelling layer includes a different material from a material of the first liquid-repelling layer.

5. The apparatus of claim 1, wherein
the head unit, in the first area, includes:
a first base layer portion;
a first layer disposed on the first base layer portion;
a first liquid-repelling layer disposed on the first layer; and
a second liquid-repelling layer disposed on the first liquid-repelling layer, and the head unit, in the second area, includes:
a second base layer portion;
a first inorganic layer on the second base layer portion; and
a second liquid-repelling layer disposed on the first inorganic layer and continuously disposed with the first area.

6. The apparatus of claim 5, wherein the first layer includes an organic material.

7. The apparatus of claim 5, wherein the first inorganic layer includes silicon dioxide (SiO₂).

8. The apparatus of claim 5, wherein a thickness of the second base layer portion in the second area is less than a thickness of the first base layer portion in the first area.

9. The apparatus of claim 5, further comprising a reinforcement layer disposed between the first inorganic layer and the second base layer portion in the second area.

10. The apparatus of claim 9, wherein the reinforcement layer includes aluminum oxide.

11. The apparatus of claim 9, wherein the reinforcement layer includes a metallic material.

12. The apparatus of claim 1, wherein, in a plan view, a nozzle hole through which ink is sprayed is defined in the second area.

13. A method for manufacturing a display apparatus, the method comprising:
preparing a head unit including a first area which is a non-damaged area and a second area which is a damaged area on a surface;
depositing an inorganic material on the surface of the head unit;
forming a second liquid-repelling layer on the surface of the head unit; and
discharging ink onto a display substrate on a stage with the head unit.

14. The method of claim 13,
wherein the first area which is the non-damaged area includes a base layer and a first liquid-repelling layer disposed on the base layer,
and the second area which is the damaged area includes a base layer.

15. The method of claim 14,
wherein the depositing the inorganic material includes depositing the inorganic material on the second area but not on the first area.

16. The method of claim 14, wherein the inorganic material is not deposited on the first liquid-repelling layer.

17. The method of claim 16,
wherein in the second area, the inorganic material is deposited to a same plane as an upper surface of the first liquid-repelling layer of the first area.

18. The method of claim 13, wherein the inorganic material includes silicon dioxide (SiO₂).

19. The method of claim 13,
wherein the forming the second liquid-repelling layer includes continuously forming the second liquid-repelling layer across the first area and the second area.

20. The method of claim 19,
wherein in the first area, the second liquid-repelling layer is disposed to overlap the first liquid-repelling layer.
